(19) United States
(12) Patent Application Publication
(10) Pub. No.: US 2008/0231336 A1
(43) Pub. Date: Sep. 25, 2008

(54) SCAN FLIP-FLOP CIRCUIT WITH EXTRA HOLD TIME MARGIN

(75) Inventors: Jeng Huang WU, Hsinchu (TW); Sheng Hua Chen, KaoHsiung (TW)

Correspondence Address: WPAT, PC, 7225 BEVERLY ST., ANNANDALE, VA, 22003, US

(73) Assignee: FARADAY TECHNOLOGY CORPORATION, Hsinchu (TW)

(21) Appl. No.: 12/049,462

(22) Filed: Mar. 17, 2008

(30) Foreign Application Priority Data
Mar. 23, 2007 (TW) 096110245

(51) Int. Cl. H03K 3/289; H03K 3/356; H03K 3/00

(52) U.S. Cl. 327/203; 327/212; 327/217

(57) ABSTRACT

The present invention is a scan flip-flop circuit with extra hold time margin. The scan flip-flop circuit includes a multiplexer, a sense amplifier and a latch. The latch includes a generation unit for generating an output signal in response to a first signal and a second signal outputted from the sense amplifier, and a storage unit receives the second signal and the output signal and maintains the output signal of the latch when the first signal and the second signal are non-activated.

### FIELD OF THE INVENTION

The present invention is related to a flip-flop circuit, and more particularly to a scan flip-flop circuit with extra hold time margin.

### BACKGROUND OF THE INVENTION

Please refer to FIG. 1, which illustrates a schematic diagram of a conventional D master-slave flip-flop. The D master-slave flip-flop comprises a master latch 10 and a slave latch 20. The master latch 10 comprises n-transistors, Mn1, Mn2, and Mn3, p-transistors Mp1, Mp2, and Mp3, and a NOT gate 12. The Mn1 and Mp1 are connected to each other to form a transmission gate 14. The input terminal of the transmission gate 14 is the input terminal (D) of the D master-slave flip-flop. A clock signal (CLK) and a complementary clock signal (CLKb) are connected respectively to gates of Mn1 and Mp1. A source of Mp3 is connected to a voltage source (Vdd). A drain of Mp3 is connected to a source of Mp2. A drain of Mp2 is connected to a drain of Mn2. A source of Mn2 is connected to a drain of Mn3. A source of Mn3 is connected to a ground (Gnd). A gate of Mp3 is connected to a gate of Mn3. The clock signal (CLK) and the complementary clock signal (CLKb) are connected respectively to the gates of Mp2 and Mn2. An output terminal of the transmission gate 14 and an input terminal of the NOT gate 12 are connected to the drain of Mp2. An output terminal of the NOT gate 12 is connected to the gate of Mp3 and is also an output terminal of the mater latch 10.

The slave latch 20 comprises n-transistors Mn4, Mn5, and Mn6, p-transistors Mp4, Mp5, and Mp6, and a NOT gate 22. The Mn4 and Mp4 are connected to each other to form a transmission gate 24. The input terminal of the transmission gate 24 is connected to the output terminal of the master latch 10; the clock signal (CLK) and the complementary clock signal (CLKb) are connected respectively to gates of Mp4 and Mn4. A source of Mp6 is connected to the voltage source (Vdd). A drain of Mp6 is connected to a source of Mp5. A drain of Mp5 is connected to a drain of Mn5. A source of Mn5 is connected to a drain of Mn6. A source of Mn6 is connected to the Ground (Gnd). A gate of Mp6 is connected to a gate of Mn6. The clock signal (CLK) and the complementary clock signal (CLKb) are connected respectively to the gates of Mn5 and Mp5. An output terminal of the transmission gate 24 and an input terminal of the NOT gate 22 are connected to the drain of Mp5. An output terminal of the NOT gate 22 is connected to the gate of Mp6 and also is an output terminal (Q) of the D master-slave flip-flop.

In the D-flip-flop shown in FIG. 1, it can be known that when the clock signal (CLK) is at the high-level, the master latch 10 is activated and the slave latch 20 is non-activated. Conversely, when clock signal (CLK) is at the low-level, the master latch 10 is non-activated and the slave latch 20 is activated. That is to say, when the input terminal of D receives the high-level and the clock signal (CLK) is at the high-level, the master latch 10 is activated and outputs the low-level. After passing by ½ cycle of the clock signal (CLK), the clock signal (CLK) changes to the low-level and activation of Mp2, Mp3 and the NOT gate 12 can latch the low-level at the output terminal of the master latch 10. At the same time, due to activation of the slave latch 20, the slave latch 20 outputs the high-level at the output terminal (Q). After further passing ½ cycle of the clock signal (CLK), the clock signal (CLK) changes to the high-level and activation of Mn5, Mn6 and the NOT gate 22 can latch the high-level at the output terminal (Q) of the D master-slave flip-flop. By the same logic, when the input terminal of the D master-slave flip-flop receives the low-level, it must pass through ½ clock cycle before the D master-slave flip-flop can output the low-level. It is easy to understand that the D master-slave flip-flop illustrated in FIG. 1 has the advantages of small area and robust but its main defect is its inability to operate at high speed.

Please refer to FIG. 2, which illustrates a conventional schematic diagram of another D master-slave flip-flop. The D master-slave flip-flop comprises a master latch 30 and a slave latch 40. The master latch 30 is also called a sense amplifier and the slave latch 40 is also called a SR latch. The master latch 30 comprises n-transistors Mn7, Mn8, Mn9, Mn10, Mn11 and Mn12, and p-transistors Mp7, Mn8, Mn9 and Mn10. A gate of Mp7 is connected to a clock terminal for receiving a clock signal (CLK); sources of Mp7 and Mp8 are connected to a voltage source (Vdd), and their drains are connected to each other to form a Set terminal (Sb) of the master latch 30. A gate of Mn7 is connected to a drain of Mn8 and a gate of Mp8. A drain of Mn7 is connected to the drain of Mp8. A drain of Mn9 is connected to a source of Mn7. A gate of Mn9 is connected to an input terminal (D) of the D master-slave flip-flop. A drain of Mn11 is connected to a source of Mn9. A gate of Mn11 is connected to the clock terminal for receiving the clock signal (CLK). A source of Mn11 is connected to a ground (Gnd). A gate of Mp10 is connected to the clock terminal for receiving the clock signal (CLK). Sources of Mp9 and Mp10 are connected to the voltage source (Vdd), and their drains are connected to each other to form a Reset terminal (Rb) of the master latch 30. A Gate of Mn8 is connected to the drain of Mn7 and a gate of Mp9. The drain of Mn8 is connected to the drain of Mp9. A drain of Mn10 is connected to a source of Mn8. A gate of Mn10 is connected to a complementary input terminal (Db) of D master-slave flip-flop. A source of Mn10 is connected to the drain of Mn11. A gate of Mn12 is connected to the voltage source (Vdd). A source and a drain of Mn12 are connected respectively to drains of Mn9 and Mn10.

The slave latch 40 comprises a pair of cross-connected NAND gates 42 and 44. One input terminal of the NAND gate 42 is connected to the Set terminal (Sb) of the master latch 30. One input terminal of the NAND gate 44 is connected to the Reset terminal (Rb) of the master latch 30. Output terminals of the NAND gates 42 and 44 in the slave latch 40 are an output terminal (Q) and a complementary output terminal (Qb) of the D master-slave flip-flop. When the Set terminal (Sb) outputs the high-level and the Reset terminal (Rb) outputs the low-level, the output terminal (Q) would output the low-level and the complementary output terminal (Qb) would output the high-level; when the Set terminal (Sb) outputs the low-level and the Reset terminal (Rb) outputs the high-level, the output terminal (Q) would output the high-level and the complementary output terminal (Qb) would output low-level; and, when the Set terminal (Sb) and the Reset terminal (Rb) output high-levels, the output terminal (Q) and the complementary output terminal (Qb) maintain at the prior-levels. Furthermore, the Set terminal (Sb) and the Reset terminal (Rb) are not allowed to output the low-levels at the same time.

When the clock signal (CLK) is at the high-level and the input terminal of the D master-slave flip-flop receives the high-level, Mn7, Mn9, Mn11 and Mn12 are “On”, Mn8 and Mn10 are “Off”, Mp9 is “On” and Mp7, Mp8 and Mp10 are “Off”. Thus, the Set terminal (Sb) outputs the low-level and the Reset terminal (Rb) outputs the high-level causing the output terminal (Q) to output the high-level and the complementary output terminal (Qb) to output the low-level. Furthermore, when the clock signal is at high-level and the input terminal of the D master-slave flip-flop receives the low-level, the Mn8, Mn10, Mn11, Mn12 are “On”, Mn7 and Mn9 are “Off”, Mp8 is “On” and Mp7, Mp9, Mp10 are “Off”. Thus, the Set terminal (Sb) outputs the high-level and the Reset terminal (Rb) outputs the low-level causing the output terminal (Q) to output the low-level and the complementary output terminal (Qb) to output the high-level. Furthermore, when the clock signal (CLK) is at low-level, regardless of the input terminal (D) of the D master-slave flip-flop, Mp7 and Mp10 in the Master Latch 30 would be “On”, hence the Set terminal (Sb) and the Reset terminal (Rb) output high-levels causing the output terminal (Q) and the complementary output terminal to maintain at the prior-levels.

As shown in FIG. 2, the output terminal (Q) and the complementary output terminal (Qb) could output corresponding-levels if the clock signal (CLK) is at the high-level. However, the two cross-connected NAND gates 42, 44 in the slave latch 40 will cause two NAND gate delay time. Therefore, to raise the operating speed of the D master-slave flip-flop is constrained.

Please refer to FIG. 3, which illustrates a schematic diagram of the D master-slave flip-flop disclosed in U.S. Pat. No. 6,232,810. The main purpose of this kind of D master-slave flip-flop is the replacement of the slave latch 40 illustrated in FIG. 2 by slave latch 60, which increases the operating speed of D master-slave flip-flop. This D master-slave flip-flop comprises a master latch 50 and a slave latch 60. The master latch 50 is also called a sense amplifier, while the slave latch 60 is also called a SR latch.

Generally speaking, there are lots of ways to realize master latch 50, such as master latches in FIG. 1 and FIG. 3 of the U.S. Pat. No. 6,232,810, hence the circuit of the master latch 50 is not emphasized. The circuit of the master latch 50 has three characteristics. (I) When the clock signal (CLK) is at the high-level and the input terminal (D) receives the high-level, the Set terminal (Sb) outputs the low-level and the Reset terminal (Rb) outputs the high-level; (II) when the clock signal (CLK) is at the high-level and the input terminal (D) receives the low-level, the Set terminal (Sb) outputs the high-level and the Reset terminal (Rb) outputs the low-level; and (III) when the clock signal (CLK) is at the low-level, the Set terminal (Sb) and the Reset terminal (Rb) output the high-levels.

The slave latch 60 comprises NOT gates 62 and 64, storage circuit 65, n-transistors Mn13 and Mn14 and p-transistors Mp11 and Mp12. In which, a gate of Mp11 is connected to the Set terminal (Sb) of the master latch 50. A source of Mp11 is connected to the voltage source (Vdd). An input terminal of the NOT gate 62 is connected to the Reset terminal (Rb) of master latch 50. A gate of Mn13 is connected to an output terminal of the NOT gate 62. A drain of Mn13 is connected to a drain of Mn11 and forms the output terminal (Q). A source of Mn13 is connected to the Ground (Gnd). A gate of Mp12 is connected to the Reset terminal (Rb) of the master latch 50. A source of Mp12 is connected to the voltage source (Vdd). An input terminal of the NOT gate 64 is connected to the Set terminal (Sb) of the master latch 50. A gate of Mn14 is connected to an output terminal of the NOT gate 64. A drain of Mn14 is connected to a drain of Mp12 and forms the complementary output terminal (Qb). A source of Mn14 is connected to the ground (Gnd). Further, the storage circuit 65 comprises NOT gates 66 and 68. The output terminal (Q) is connected to an input terminal of the NOT gate 68 and an output terminal of the NOT gate 66. The complementary output terminal (Qb) is connected to an output terminal of the NOT gate 68 and an input terminal of the NOT gate 66.

Therefore, when the Set terminal (Sb) of the master latch 50 outputs the low-level and the Reset terminal (Rb) outputs the high-level, the output terminal (Q) and the complementary output terminal (Qb) rapidly output the high-level and the low-level respectively. When the Set terminal (Sb) of the master latch 50 outputs the high-level and the Reset terminal (Rb) outputs the low-level, the output terminal (Q) and the complementary output terminal (Qb) rapidly output the low-level and the high-level respectively. Further, when the Set terminal (Sb) and the Reset terminal (Rb) of the master latch 50 output the high-levels, the output terminal (Q) and the complementary output terminal (Qb) maintain at the prior levels. That is, there is no NAND gate delay time for D master-slave flip-flop as in FIG. 3, so the operating speed would be faster than that of D master-slave flip-flop in FIG. 2.

The slave latch 60 of D master-slave flip-flop in FIG. 3 has a symmetric circuit structure, thus this kind of D master-slave flip-flop can output complementary levels from Q and Qb at the same time. As commonly known, two transistors are needed to realize a NOT gate. Thus the slave latch 60 needs a total of 12 transistors to realizing, which would occupy larger layout area.

In the IC design field, in addition to designing the path for transmitting general data, one needs to design another path for testing the circuit. That is to say, when the designed circuit is under test mode, the input terminal of the circuit has to receive test data for test. When the designed circuit is under operation mode, the input terminal of the circuit has to receive general data. In order to achieve the above functions, a multiplexer 70 is added in the stage before the input terminal of the flip-flop to form a scan flip-flop. Please refer to FIG. 4, which illustrates a schematic diagram of the scan flip-flop. When the select terminal (SEL) of the multiplexer 70 receives the low-level, it means that the scan flip-flop is under operation mode, during which the signal from the data input terminal (Da) could be inputted into D flip-flop 80. Conversely, when the select terminal (SEL) of the multiplexer 70 receives the high-level, it means that the scan flip-flop is under the test mode during which the signal from the test input terminal (TD) could be inputted into D flip-flop 80.

Generally speaking, transmitting speed of test data from the test data input terminal (TD) is slower when the scan flip-flop is under the test mode. Thus, operation of the D flip-flop 80, such as the D master-slave flip-flop in FIG. 3, causes the hold time margin under test mode to be too short and the scan flip-flop is made unable to work normally. To solve the problem describing above, the data-transmitting path can be connected to a number of buffers in series in order to increase hold time margin. However, the addition of buffers would also result in increase of transistors and increase the layout area.

Therefore, how to improve the layout area of the conventional D master-slave flip-flop and providing a scan flip-flop with extra hold time margin are the main purposes of the present invention.

### SUMMARY OF THE INVENTION

The object of the present invention is to improve the layout area of the D master-slave flip-flop and providing a scan flip-flop with extra hold time margin.

The present invention provides a scan flip-flop circuit comprising: a flip-flop; and a multiplexer including: a data transmitting circuit having at least 2 p-transistors and 2 n-transistors cascaded between a voltage source and a ground in sequence, a connecting point of one p-transistor and one n-transistor being an output terminal of the data transmitting circuit coupled to an input terminal of the flip-flop, gates of one p-transistor and one n-transistor being respectively connected to a select terminal and a complementary select terminal of the multiplexer, gates of the other p-transistor and the other n-transistor being connected to a first data input terminal of the multiplexer; and, a test data transmitting circuit having at least 2 p-transistors and 2+N n-transistors cascaded between the voltage source and the ground in sequence, a connecting point of one p-transistor and one n-transistor being an output terminal of the test data transmitting circuit coupled to an input terminal of the flip-flop, gates of one n-transistor and one p-transistor being connected to the select terminal and the complementary select terminal respectively; wherein, when the select terminal receives a first level, the first data input terminal of the data transmitting circuit transmits a data signal to the output terminal of the data transmitting circuit and when the select terminal receives a second level, the second data input terminal of the test data transmitting circuit transmits a test data signal to the output terminal of the test data transmitting circuit and N is greater than 1.

Furthermore, the present invention provides a master-slave flip-flop circuit comprising: a sense amplifier generating a first signal and a second signal in response to an input signal and a clock signal, wherein when the clock signal is at a first-level and the input terminal receives the first-level, the first signal is an activated signal and the second signal is a non-activated signal indicating a first state of the sense amplifier; when the clock signal is at a first-level and the input terminal receives a second-level, the first signal is the non-activated signal and the second signal is the activated signal indicating a second state of the sense amplifier; and when the clock signal is at the second-level, the first signal and the second signal are the non-activated signals indicating a third state of the sense amplifier; and, a latch comprising a generation unit receiving the first signal and the second signal for generating an output signal of the master-slave flip-flop and a storage circuit receiving the output signal and the second signal for maintaining the output signal during the third state of the sense amplifier; wherein, the generating unit comprises a first p-transistor having a gate receiving the first signal and a source connected to a voltage source, a NOT gate having an input terminal receiving the second signal, and a n-transistor having a gate connected to a output terminal of the NOT gate, a drain connected to a drain of the p-transistor and being the output terminal of the master-slave flip-flop, and a source connected to a ground, and the output signal generated by the generating unit during the first state of the sense amplifier and the output signal generated by the generating unit during the second state of the sense amplifier are complementary.

Furthermore, the present invention provides a SR latch circuit comprising: a generation unit receiving a first signal and a second signal for generating an output signal of the SR latch, wherein three states are determined in response to the first signal and the second signal including a first state with a activated first signal and a non-activated second signal, a second state with a non-activated first signal and a activated second signal, and a third state with the non-activated first signal and the non-activated second signal; and, a storage circuit receiving the output signal and the second signal for maintaining the output signal during the third state; wherein, the generating unit comprises a first p-transistor having a gate receiving the first signal and a source connected to a voltage source, a NOT gate having an input terminal receiving the second signal, and a n-transistor having a gate connected to a output terminal of the NOT gate, a drain connected to a drain of the p-transistor and being the output terminal of the master-slave flip-flop, and a source connected to a ground, and the output signal generated by the generating unit during the first state and the output signal generated by the generating unit during the second state are complementary.

The above contents of the present invention will become more readily apparent to those ordinarily skilled in the art after reviewing the following detailed description and accompanying drawings, in which:

### BRIEF DESCRIPTION OF THE DRAWINGS

FIG. 1 illustrates a schematic diagram of a conventional D master-slave flip-flop.

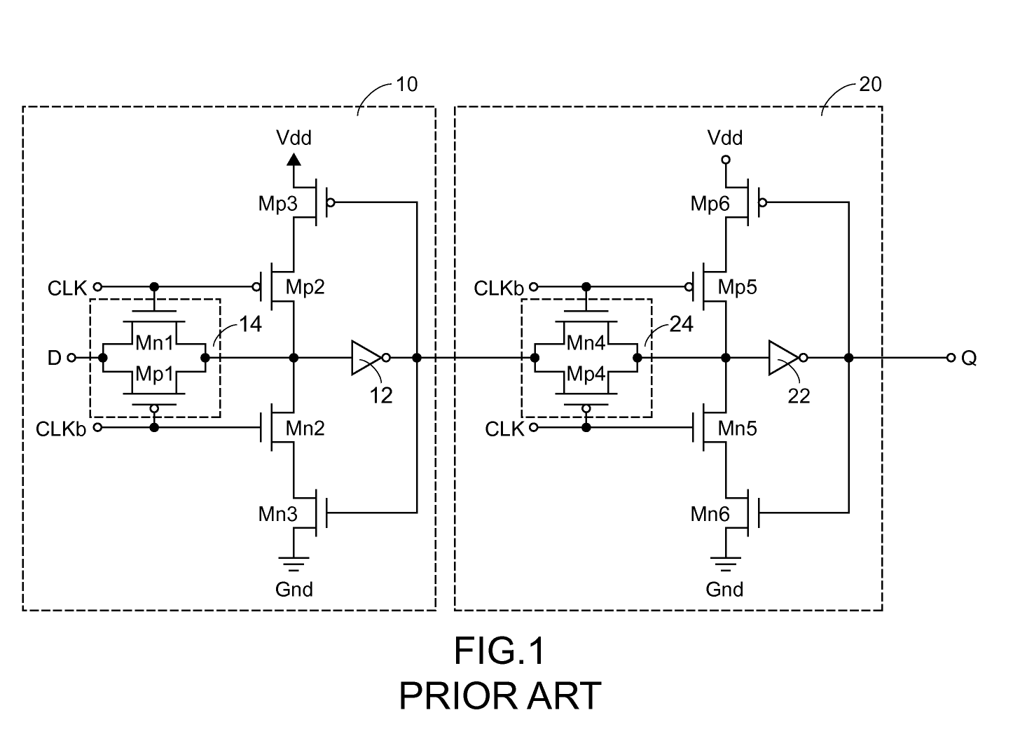

FIG. 2 illustrates a conventional schematic diagram of another D master-slave flip-flop.

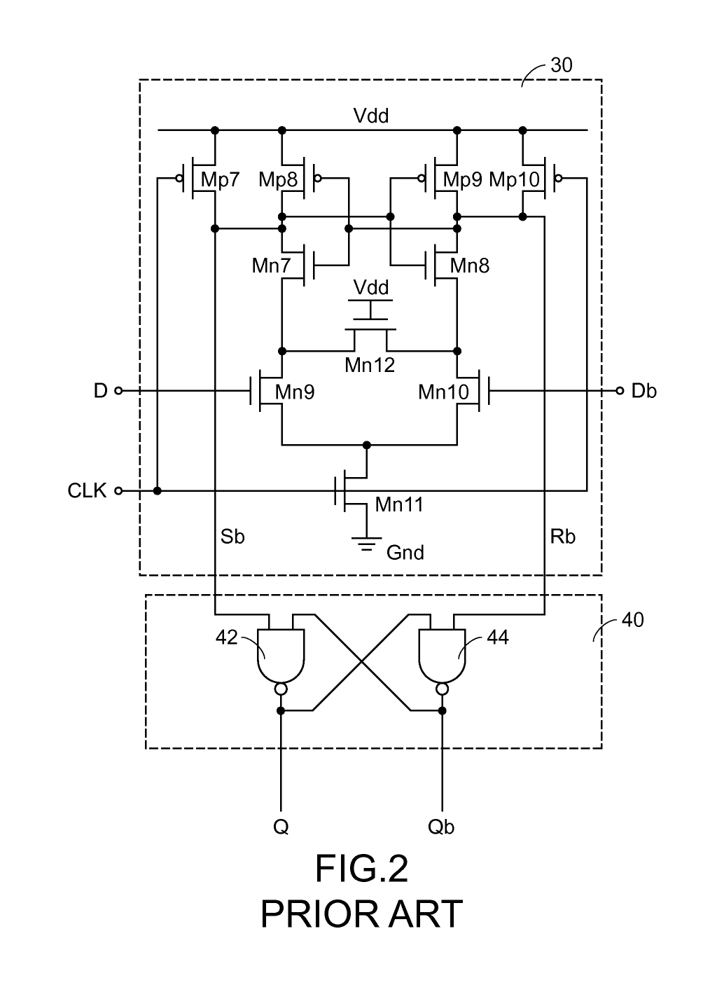

FIG. 3 illustrates a schematic diagram of the D master-slave flip-flop disclosed in U.S. Pat. No. 6,232,810.

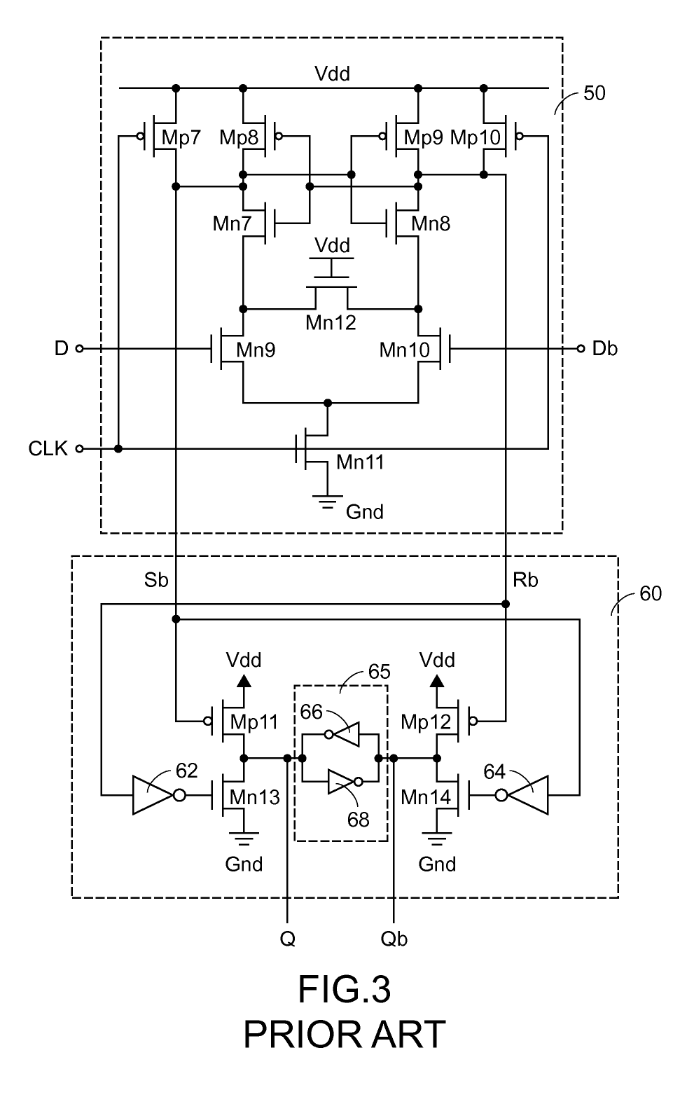

FIG. 4 illustrates a schematic diagram of the scan flip-flop.

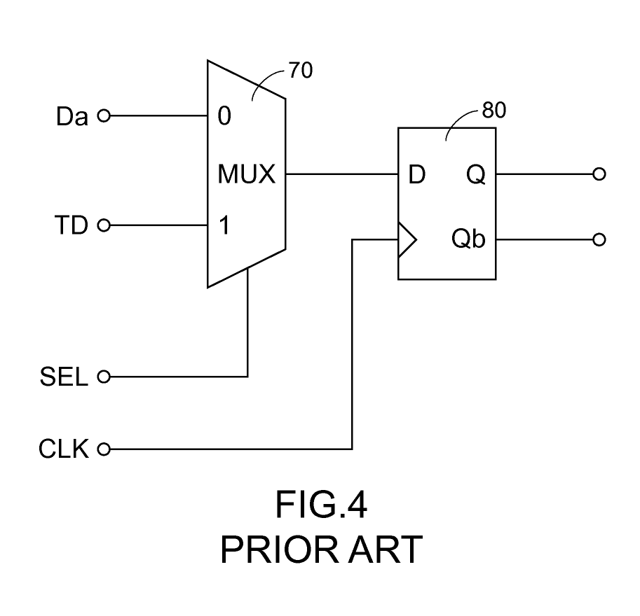

FIG. 5 illustrates a schematic diagram of the D master-slave flip-flop of the present invention.

FIG. 6 illustrates a schematic diagram of the NAND gate.

FIG. 7 illustrates a schematic diagram of the scan flip-flop of the present invention.

### DETAILED DESCRIPTION OF THE PREFERRED EMBODIMENT

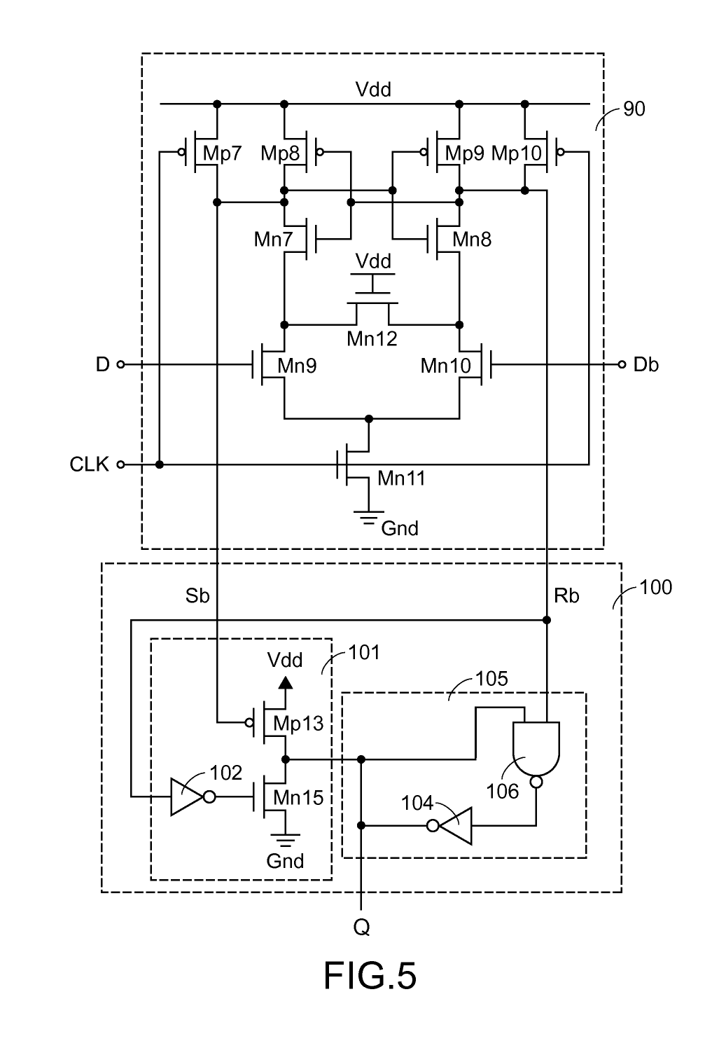

Please refer to FIG. 5, which illustrates a schematic diagram of the D master-slave flip-flop of the present invention. The D master-slave flip-flop of the present invention provides a slave latch 100 with fewer transistors. Furthermore, it is not constrained to the circuit structure of the master latch 90. The master latch 90, also referred to as a sense amplifier, has the following characteristics: (I) When the clock signal (CLK) is at the first-level and the input terminal (D) receives the high-level, the Set terminal (Sb) outputs the low-level and the Reset terminal (Rb) outputs the high-level; (II) when the clock signal (CLK) is at the first-level and the input terminal (D) receives the low-level, the Set terminal (Sb) outputs the high-level and the Reset terminal (Rb) outputs the low-level; and (III) when the clock signal (CLK) is at the second-level, the Set terminal (Sb) and the Reset terminal (Rb) output the high-levels. Furthermore, the first-level and the second-level of the clock Signal (CLK) are complementary.

The slave latch 100, also called a SR latch, comprises a generation unit 101 and a storage circuit 105. The generation unit 101 comprises a NOT gate 102, n-transistors Mn15 and P-transistors Mp13. In the generation unit 101, a gate of Mp13 is connected to the Set terminal (Sb) of the master latch 90. A source of Mp13 is connected to the voltage source (Vdd). An input terminal of the NOT gate 102 is connected to the Reset terminal (Rb) of the master latch 90. A gate of Mn15 is connected to an output terminal of NOT gate 102. A drain of Mn15 is connected to a drain of Mp13 and forms output terminal (Q) of the D master-slave flip-flop. A source of Mn15 is connected to the ground (Gnd). The storage circuit 105 comprises a NOT gate 104 and a NAND gate 106, in which, one input terminal of the NAND gate 106 is connected to the output terminal (Q), the other input terminal of the NAND gate 106 is connected to the Reset terminal (Rb) of the master latch 90. An output terminal of the NAND gate 106 is connected to an input terminal of the NOT gate 104. An output terminal of the NOT gate 104 is connected to the output terminal (Q) of the D master-slave flip-flop.

Therefore, when the Set terminal (Sb) of the master latch 90 outputs the low-level and the Reset terminal (Rb) outputs the high-level, the output terminal (Q) of the slave latch 100 can rapidly output the high-level, and the NAND gate 106 of storage circuit 105 outputs low-level and the NOT gate 104 outputs the high-level. When the Set terminal (Sb) of the master latch 90 changes to the high-level and the Reset terminal (Rb) remains at the high-level, the storage circuit 105 of slave latch 100 can maintain the prior level (high-level) at the output terminal (Q).

Furthermore, when the Set terminal (Sb) of the master latch 90 outputs the high-level and the Reset terminal (Rb) outputs the low-level, the output terminal (Q) of the slave latch 100 can rapidly output the low-level, and the NAND gate 106 of storage circuit 105 outputs high-level and the NOT gate 104 outputs the low-level. When the Set terminal (Sb) of the master latch 90 remains at the high-level and the Reset terminal (Rb) changes to the high-level, the storage circuit 105 of slave latch 100 can maintain the prior level (low-level) at the output terminal (Q).

That is to say, when the Set terminal (Sb) and the Reset terminal (Rb) respectively output an activated signal and a non-activated signal, the output terminal (Q) of the slave latch 100 can output the high-level. Conversely, when the Set terminal (Sb) and the Reset terminal (Rb) respectively output the non-activated signal and the activated signal, the output terminal (Q) of the slave latch 100 can output the low-level. Further, when both the Set terminal (Sb) and the Reset terminal (Rb) output the non-activated signals, the output terminal (Q) of the slave latch 100 can maintain at the prior level.

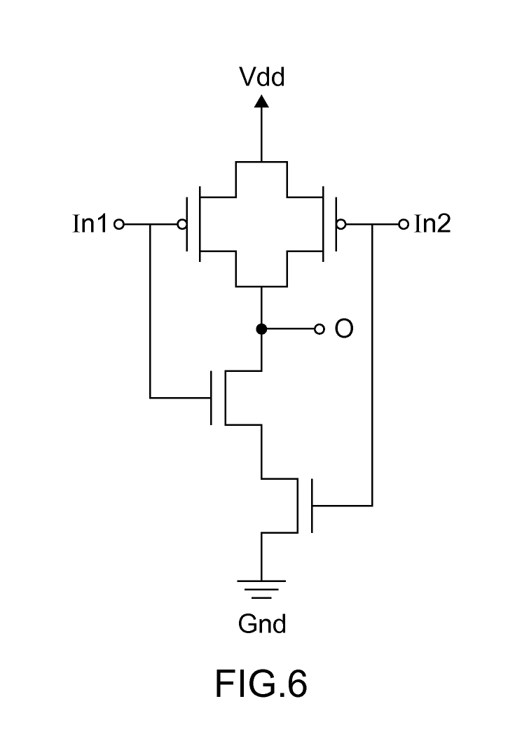

Please refer to FIG. 6, which illustrates a schematic diagram of the NAND gate. As illustrated, when two inputs In1 and In2 are high-level, the cascaded two n-transistors are switched On, an output (O) of the NAND gate becomes the low-level. When two inputs In1 and In2 are low-levels or either one is low-level, the output (O) of the NAND gate becomes the high-level. Thus, the presented invention only needs 10 transistors (4 transistors for one NAND gate 106, 4 transistors for two NOT gates 102, 104, Mp13, and Mn15) to realize the slave latch 100 (SR latch).

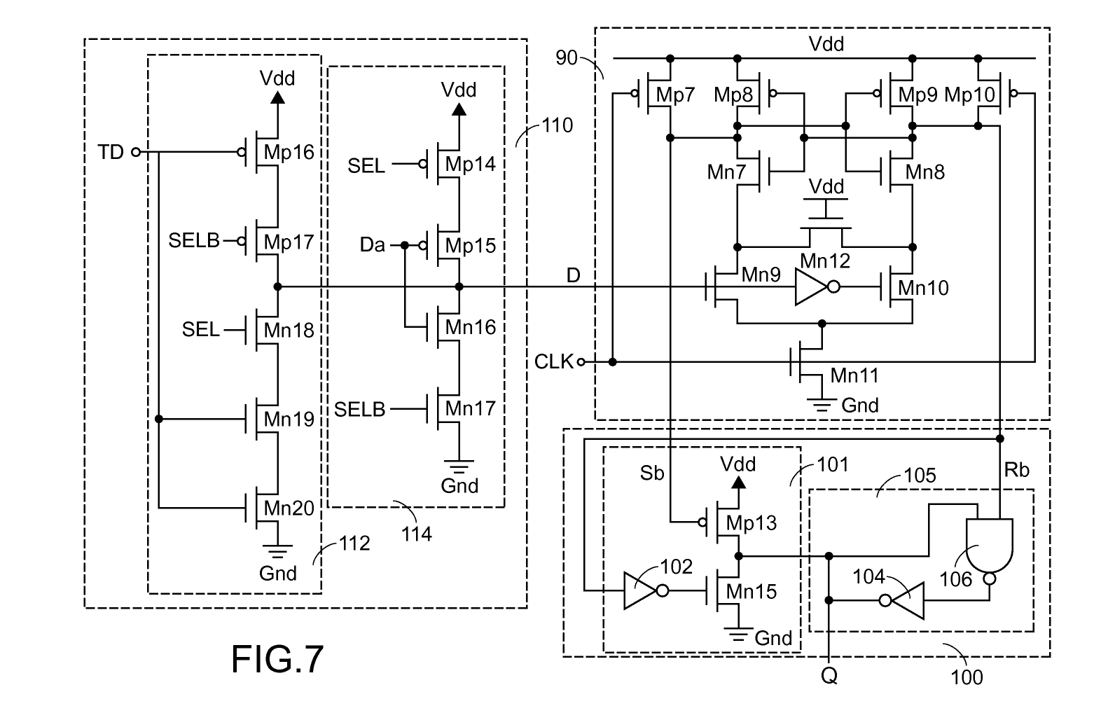

Please refer to FIG. 7, which illustrates a schematic diagram of the scan flip-flop of the present invention. The scan flip-flop comprises a multiplexer 110 and a D master-slave flip-flop. The multiplexer 110 comprises a data transmitting circuit 114 and a test data transmitting circuit 112. The data transmitting circuit 114 comprises two P-transistors Mp14 and Mp15 and two n-transistors Mn16 and Mn17 that are cascaded between voltage source (Vdd) and the ground (GND) in sequence. The connecting point of Mp15 and Mn16 is the output terminal of the data transmitting circuit 114, which is the output terminal of the multiplexer 110, which is connected to the input terminal (D) of the D master-slave flip-flop. Gates of Mp14 and Mn17 are respectively connected to the select terminal (SEL) and the complementary select terminal (SELB) respectively. Gates of Mp15 and Mn16 are connected to the data input terminal (Da) of the multiplexer 110. According to embodiment of the present invention, the data transmitting circuit 114 comprises two P-transistors and two n-transistors that are cascaded between the voltage source (Vdd) and the ground (GND). In practical application, more P-transistors and n-transistors cascaded between the voltage source (Vdd) and the ground (GND) are allowed for achieving the same function of the data transmitting circuit 114.

The test data transmitting circuit 112 comprises two P-transistors Mp16 and Mp17, and three n-transistors Mn18, Mn19 and Mn20 that are cascaded between the voltage source (Vdd) and the ground (GND) in sequence. The connecting point of Mp17 and Mn18 is the output terminal of the test data transmitting circuit 112, which is connected to the output terminal of the multiplexer 110. Gates of Mn18 and Mp17 are connected to the select terminal (SEL) and the complementary select terminal (SELB) respectively. Gates of Mp16, Mn19 and Mn20 are connected to the test data input terminal (TD) of the multiplexer 110. According to embodiment of the present invention, the test data transmitting circuit 112 comprises two P-transistors and three n-transistors that are cascaded between the voltage source (Vdd) and the ground (GND). In practical application, more P-transistors and n-transistors cascaded between the voltage source (Vdd) and the ground (GND) are allowed for achieving the same function of the test data transmitting circuit 112.

According to embodiment of the present invention, transmitting speed of the test data from the test data input terminal (TD) is slower when the scan flip-flop is under the test mode (SEL is high-level). Thus, the present invention increases the number of cascaded n-transistors Mn19 and Mn20, to achieve the purpose of increasing the hold time margin, and to enable scan flip-flop to work normally under test mode. The number of cascaded n-transistors can be increased or reduced according to the need for maintaining hold time margin in practice. The presented invention is not constrained to the number of cascaded n-transistors in the test data transmitting circuit 112.

The present invention of the scan flip-flop is not constrained to the combination of the invented multiplexer 110 and the invented D master-slave flip-flop. Other scan flip-flop combined with the invented multiplexer 110 and other flip-flop can also realize the effect of increasing hold time margin of the presented invention.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A scan flip-flop circuit comprising:
a flip-flop; and
a multiplexer including:
a data transmitting circuit having at least 2 p-transistors and 2 n-transistors cascaded between a voltage source and a ground in sequence, a connecting point of one p-transistor and one n-transistor being an output terminal of the data transmitting circuit coupled to an input terminal of the flip-flop, gates of one p-transistor and one n-transistor being respectively connected to a select terminal and a complementary select terminal of the multiplexer, gates of the other p-transistor and the other n-transistor being connected to a first data input terminal of the multiplexer; and
a test data transmitting circuit having at least 2 p-transistors and 2+N n-transistors cascaded between the voltage source and the ground in sequence, a connecting point of one p-transistor and one n-transistor being an output terminal of the test data transmitting circuit coupled to an input terminal of the flip-flop, gates of one n-transistor and one p-transistor being connected to the select terminal and the complementary select terminal respectively;
wherein, when the select terminal receives a first level, the first data input terminal of the data transmitting circuit transmits a data signal to the output terminal of the data transmitting circuit and when the select terminal receives a second level, the second data input terminal of the test data transmitting circuit transmits a test data signal to the output terminal of the test data transmitting circuit and N is greater than 1.

2. The scan flip-flop circuit according to claim 1, wherein the flip-flop is a D flip-flop.

3. A master-slave flip-flop circuit comprising:
a sense amplifier generating a first signal and a second signal in response to an input signal and a clock signal, wherein when the clock signal is at a first-level and the input terminal receives the first-level, the first signal is an activated signal and the second signal is a non-activated signal indicating a first state of the sense amplifier; when the clock signal is at a first-level and the input terminal receives a second-level, the first signal is the non-activated signal and the second signal is the activated signal indicating a second state of the sense amplifier; and when the clock signal is at the second-level, the first signal and the second signal are the non-activated signals indicating a third state of the sense amplifier; and
a latch comprising a generation unit receiving the first signal and the second signal for generating an output signal of the master-slave flip-flop and a storage circuit receiving the output signal and the second signal for maintaining the output signal during the third state of the sense amplifier;
wherein, the generating unit comprises a first p-transistor having a gate receiving the first signal and a source connected to a voltage source, a NOT gate having an input terminal receiving the second signal, and a n-transistor having a gate connected to a output terminal of the NOT gate, a drain connected to a drain of the p-transistor and being the output terminal of the master-slave flip-flop, and a source connected to a ground, and the output signal generated by the generating unit during the first state of the sense amplifier and the output signal generated by the generating unit during the second state of the sense amplifier are complementary.

4. The master-slave flip-flop circuit according to claim 3, wherein the latch is a SR latch.

5. The master-slave flip-flop circuit according to claim 3, wherein the first signal is a set signal and the second signal is a reset signal.

6. The master-slave flip-flop circuit according to claim 3, wherein the storage circuit comprises:
a NAND gate having a first input terminal receiving the second signal and a second input terminal receiving the output signal of the master-slave flip-flop; and
a NOT gate having an input terminal connected to an output terminal of the NAND gate, and an output terminal connected to the second terminal of the NAND gate.

7. A SR latch circuit comprising:
a generation unit receiving a first signal and a second signal for generating an output signal of the SR latch, wherein three states are determined in response to the first signal and the second signal including a first state with a activated first signal and a non-activated second signal, a second state with a non-activated first signal and a activated second signal, and a third state with the non-activated first signal and the non-activated second signal; and
a storage circuit receiving the output signal and the second signal for maintaining the output signal during the third state;
wherein, the generating unit comprises a first p-transistor having a gate receiving the first signal and a source connected to a voltage source, a NOT gate having an input terminal receiving the second signal, and a n-transistor having a gate connected to a output terminal of the NOT gate, a drain connected to a drain of the p-transistor and being the output terminal of the master-slave flip-flop, and a source connected to a ground, and the output signal generated by the generating unit during the first state and the output signal generated by the generating unit during the second state are complementary.

8. The SR latch circuit according to claim 7, wherein the first signal is a set signal and the second signal is a reset signal.

9. The SR latch circuit according to claim 7, wherein the storage circuit comprises:
a NAND gate having a first input terminal receiving the second signal and a second input terminal receiving the output signal of the master-slave flip-flop; and
a NOT gate having an input terminal connected to an output terminal of the NAND gate, and an output terminal connected to the second terminal of the NAND gate.

10. The SR latch circuit according to claim 7, wherein the first signal and the second signal are generated by a sense amplifier.
